(19) United States
(12) Patent Application Publication
(10) Pub. No.: US 2005/0006701 A1
(43) Pub. Date: Jan. 13, 2005

(54) High voltage metal-oxide semiconductor device

(76) Inventors: Tzu-Chiang Sung, Hsinchu City (TW); Cheng-Fu Hsu, Taichung City (TW)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/614,462

(22) Filed: Jul. 7, 2003

(51) Int. Cl. H01L 29/76; H01L 29/94

(52) U.S. Cl. 257/339; 257/341

(57) ABSTRACT

A high voltage device comprising a substrate of a first type, a first and second well respectively of the first and a second type in the substrate, a gate formed on the substrate, a first and second doped region both of the second type, respectively formed in the first and second well and both sides of the gate, and a third doped region of the first type in the first well and adjacent to the first doped region.

### BACKGROUND OF THE INVENTION

1. Field of the Invention

The present invention relates to a high voltage device and particularly to HVPMOS and HVNMOS having a novel drain structure affording a high breakdown voltage.

2. Description of the Prior Art

High-voltage metal-oxide-semiconductor (HVMOS) transistors are widely used in many electrical devices, such as CPU power supplies, power management systems, AC/DC converters, and the like.

HVMOS transistors are typically used under high operational voltage, and the resulting high electric field leads to the incurrence of numerous hot electrons around the junction of the channel and drain. These hot electrons affect covalent electrons around the drain by causing many electron-hole pairs through the lifting of the electrons around the drain to conductive bands. Most of the ionized electrons resulting from the hot electrons move to the drain and increase the drain current I_{d} and a small portion of the ionized electrons are injected into and become trapped in the gate oxide layer to cause a shift in the gate threshold voltage. Conversely, the holes caused by hot electrons flow to the substrate and produce a substrate current I_{sub}. As the operational voltage increases, the quantity of electron-hole pairs correspondingly increases to lead creating the phenomenon known as carrier multiplication.

FIG. 1 is a cross-sectional diagram of a conventional HVMOS transistor with lateral diffuse drains. As shown in FIG. 1, the HVMOS transistor 130 is fabricated on a semiconductor wafer 110. The semiconductor wafer 110 comprises a P-type silicon substrate 111 and a P-type epitaxial layer 112 formed on the surface of the P-type silicon substrate 111. The HVMOS transistor 130 comprises a P-well region 121, an N-type source 122 formed within the P-well region 121, an N-type drain 124 formed in the P-type epitaxial layer 112, and a gate 114.

When the above-mentioned substrate current I_{sub} flows through the silicon substrate 111, the native resistance R_{sub} of the silicon substrate 111 induces an inductive voltage (V_{b}). If the inductive voltage V_{b} is sufficiently large, a forward bias between the silicon substrate 111 and the source 122 will be produced and simultaneously form what is termed as a parasitic bipolar junction transistor 140. When the parasitic bipolar junction transistor 140 is turned on, current flow from the drain 124 to the source 122 abruptly increases to cause the snap-back phenomenon and produce a defective HVMOS 130. The smallest drain voltage to cause the snap-back phenomenon is termed snapback voltage. Also, the channel conductance of the HVMOS 130 of the prior art is not sufficient so that inferior current drifting occurs to easily resulting in the snap-back phenomenon.

However, in some HVMOS transistors, a double diffuse drain (DDD) has been extensively applied to the source/drain (S/D) structure in order to provide a higher breakdown voltage. FIG. 2 is a cross-sectional diagram of an HVMOS transistor with double diffuse drain taught in the prior art disclosed in U.S. Pat. No. 5,770,880. A substrate 210 has an n-type body 212. A gate 220 on a gate oxide 222 extends between a source 230 and drain 240. The source and drain are essentially identical. So, further reference will only be made to the drain, but it is understood that the source can be substituted for the drain. Each drain has a double diffusion consisting of a first heavily doped contact region 214 and a more lightly doped drain region 216. The diffusions are made by opening apertures 219 in oxide layer 218, implanting the exposed surface of substrate 210 with p-type ions (e.g. boron) and annealing the implant to diffuse the ions into the substrate 216 to form p-type regions 214 and 216. The contact region 214 is generally confined to the surface and does not extend deeply into the n-type body 212. The second more lightly doped p-type region 216 extends deeply into the body 212 and partially beneath the gate 220. Region 216 forms a junction with the n-type body 212 and that junction establishes the breakdown voltage for the device 210. The diffusion 216 has a low doped concentration gradient that reduces the electric field which forms around the reverse bias body drain junction. This allows a higher voltage to be applied to the device before breakdown is reached.

The high surface concentration and low resistivity p+ regions 214 are often formed in the drain and source regions to reduce the series resistance between the channel and a metal contact (not shown) where channel current flows through them. Such high concentration regions also reduce contact resistance between the contact metal and the region itself. The high surface concentration regions 214 can be defined by the same mask (e.g. oxide layer 218 and apertures 219) that is used to define the source and drain diffusions 216 which result in the conventional double diffused structure. Alternatively, the high concentration regions 214 can be defined using a different mask from that used to define the drains 216. The different masks provide greater flexibility for setting the lateral space between the edge of the high concentration layer 214 and the edge of the low concentration layer 216.

As well, the double diffuse drain helps to suppress the hot electron effect caused by the short channel effect of the MOS transistor to further avoid electrical breakdown of the source/drain under high operational voltage. However, the above-mentioned snapback voltage degradation problem caused by the substrate current still cannot be thoroughly resolved. Therefore, importance lies in the resolution of the above-mentioned problem as well as to greatly increase the junction breakdown voltage.

Turning to FIG. 3, there is shown an illustration of a cross section of a HVPMOS disclosed in U.S. Pat. No. 5,770,880 as its invention. The device 3100 of FIG. 3 has a semiconductor substrate 310 with an n-type body 312. Heavily p-type doped source drain contact diffusions 314 provide contact to conductors connected to other devices or to external electrical circuits. The respective source and drain regions 316 are formed by a non self aligned mask sequence for the heavily doped region 314 and the lightly doped region 316. Region 316 is formed by making an opening 319 in layer 318 where the lightly doped region is implanted, typically with boron, and diffused. Then region 314 is formed by reopening 319 (aligned and re-sized as needed) and implanting the heavily doped region, also typically boron, and diffusing it. The graded, lightly doped p-type region 316 extends slightly beneath the outer edges of gate 320. The channel region 313 extends between the respective boundaries of the source drain regions and the n-type body region 312. At the surface of the substrate 310 proximate to the boundary between the source drain diffusions 316 and the body 312, there are moderately doped p-type implant regions 350. The moderately doped p-type implants 350 have a concentration greater than the source drain regions 316 but substantially less than the more heavily doped p-type contact regions 314. The moderately doped p-type regions 350 counteract the depletion effect of an irradiated gate 320 and thereby lower the on resistance of the PMOS device 3100. However, the moderate p-type implants 350 are sufficiently shallow and small enough so that they do not substantially alter the breakdown voltage formed by the junction of the p-type drain regions 316 and the n-type body 12. As such, the device 3100 retains its breakdown voltage in the region of 40-100 volts and will still turn on even after the gate 320 is subjected to radiation.

However, there is no HVMOS optimally applicable for devices with an operating voltage between 20V and 40V. The HVMOS with double diffuse drains should operate at a voltage lower than 20V while that with lateral diffuse drains may operate at a voltage above 40V. For some applications using an operating voltage between 20V and 40V, the double diffuse drain structure cannot tolerate such a high operating voltage. Although the lateral diffuse drain structure could be used for those applications, it occupies a circuit area larger than the double diffuse drain structure.

### SUMMARY OF THE INVENTION

The object of the present invention is to provide a high voltage device combining the advantage of double and lateral diffuse drain structures, which sustain high voltage of between 20V and 40V without occupying a large circuit area.

The present invention provides a first high voltage device comprising a substrate of a first type, a first and second well respectively of the first and a second type in the substrate, a gate formed on the substrate, a first and second doped region both of the second type, respectively formed in the first and second well and both sides of the gate, and a third doped region of the first type in the first well and adjacent to the first doped region.

The present invention provides a second high voltage device formed on a P substrate comprising a HVNMOS and a HVPMOS. The HVNMOS comprises a first P and N well in the P substrate, a first gate formed on the P substrate, two first N+ doped regions respectively formed in the first P and N well, and both sides of the first gate, and a first P+ doped region in the first P well and adjacent to the first N+ doped region in the first P well. The HVPMOS comprises a N+ buried layer in the P substrate, a second N and P well in the P substrate and above the N+ buried layer, a second gate formed on the P substrate, two second P+ doped regions respectively formed in the second N and P well, and both sides of the second gate, and a second N+ doped region in the second N well and adjacent to the second P+ doped region in the second N well.

The present invention further provides a first method for manufacturing a high voltage device, comprising the steps of providing a substrate of a first type, forming a first and second well respectively of the first and a second type in the substrate, forming a gate on the substrate, forming a first and second doped region both of the second type, respectively in the first and second well and both sides of the gate, and forming a third doped region of the first type in the first well and adjacent to the first doped region.

The present invention also provides a second method for manufacturing a high voltage device comprising the steps of providing a P substrate, forming a HVNMOS on the P substrate by forming a first P and N well in the P substrate, forming a first gate on the P substrate, forming two first N+ doped regions respectively in the first P and N well, and both sides of the first gate, and forming a first P+ doped region in the first P well and adjacent to the first N+ doped region in the first P well, and forming a HVPMOS on the P substrate by forming a N+ buried layer in the P substrate, forming a second N and P well in the P substrate and above the N+ buried layer, forming a second gate on the P substrate, forming two second P+ doped regions respectively in the second N and P well, and both sides of the second gate, and forming a second N+ doped region in the second N well and adjacent to the second P+ doped region in the second N well.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1 is a cross-sectional diagram of a conventional HVMOS transistor.

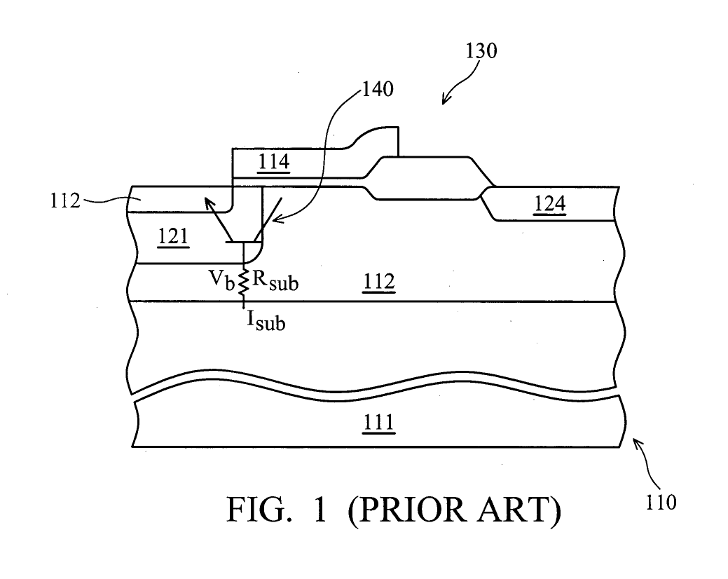

FIG. 2 is a cross-sectional diagram of a conventional HVMOS transistor with double diffuse drains.

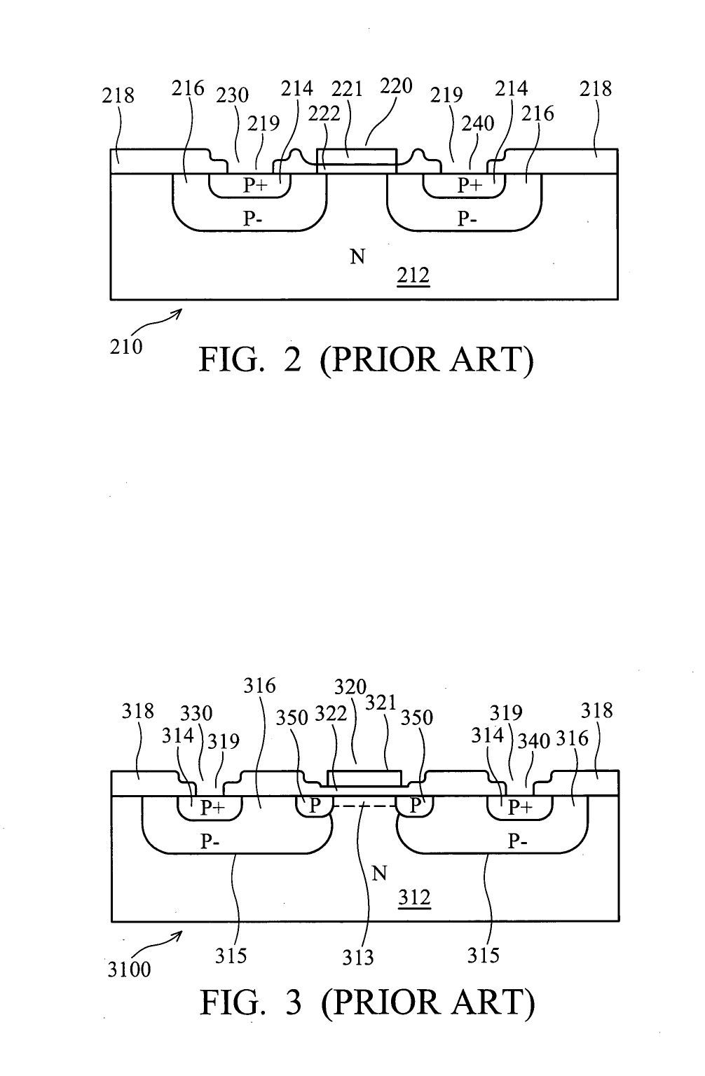

FIG. 3 shows an illustration of a cross section of a conventional HVPMOS.

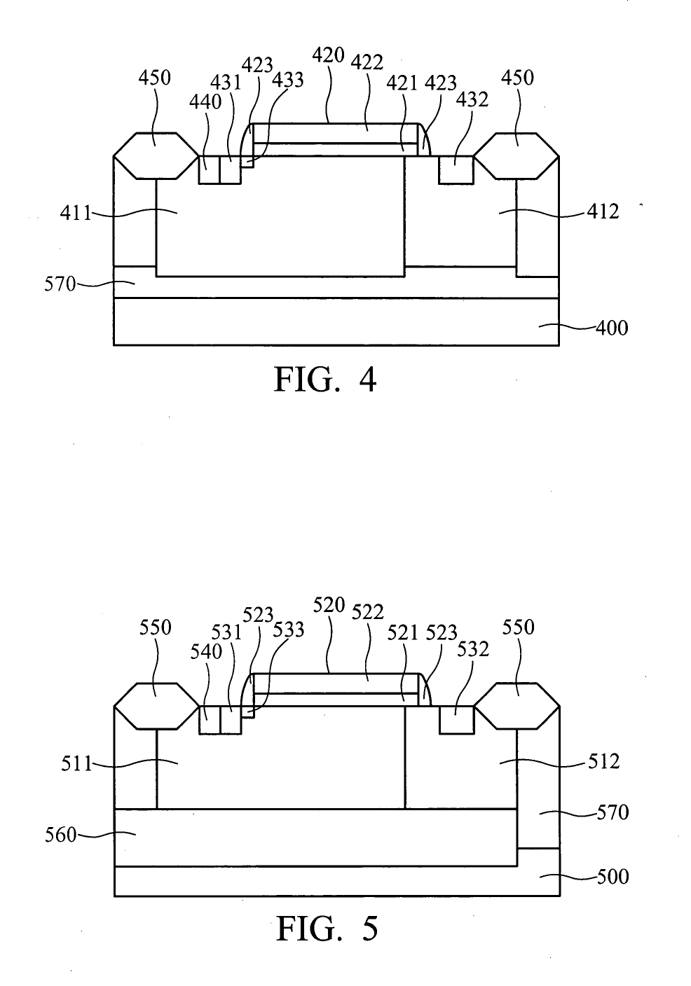

FIG. 4 is a cross-sectional diagram of a HVNMOS transistor according to one embodiment of the invention.

FIG. 5 is a cross-sectional diagram of a HVPMOS transistor according to one embodiment of the invention.

FIG. 6A˜6F are diagrams showing a manufacturing method of a high voltage device according to one embodiment of the invention.

### DETAILED DESCRIPTION OF THE INVENTION

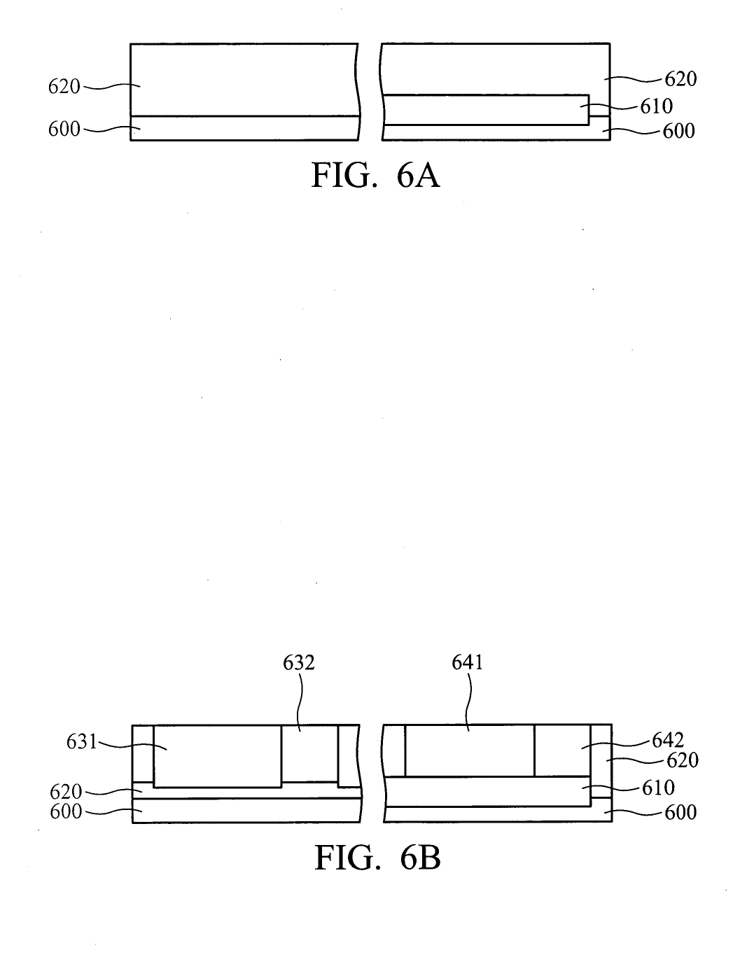

FIG. 4 is a cross-sectional schematic diagram of the HVNMOS transistor formed on a P substrate 400 according to one embodiment of the invention. As shown in FIG. 4, a P well 411 and N well 412 are formed in the P substrate 400. A gate structure 420 is formed on the P substrate 400 and includes a gate oxide 421 on the P substrate 400, a conducting layer (poly-silicon) 422 on the gate oxide 421 and spacers 423 on two sides of the gate oxide 421 and conducting layer 422. A first and second N+ doped region 431 and 432 are respectively formed in the P well 411 and N well 412, and both sides of the gate structure 420. An N lightly doped region 433 is formed adjacent to the first N+ doped region 431 and beneath one of the spacers 423. A P doped region 440 is formed in the P well 411 and adjacent to the first N+ doped region 431. Field oxides 450 isolate the HVNMOS transistor from other devices on the P substrate 400. The doped regions 440 and 431 form the source of the HVNMOS transistor while the doped region 432 forms the drain of the HVNMOS transistor. The spacing of the second N+ doped region 432 to the edge of the gate structure 420 should be an appropriate value so that the drain side of the HVNMOS sustains a high breakdown voltage. The overlay of the gate structure 420 and the N well 412 is defined as zero.

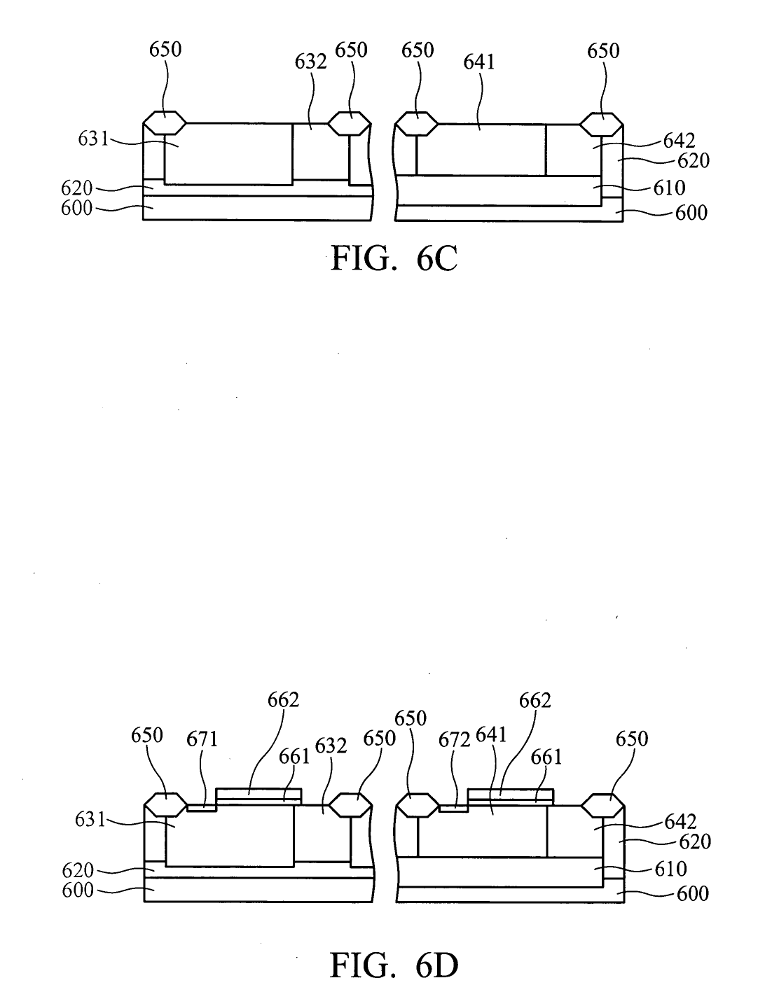

FIG. 5 is a cross-sectional schematic diagram of the HVPMOS transistor made on a P substrate 500 according to one embodiment of the invention. As shown in FIG. 5, an N well 511 and P well 512 are formed in the P substrate 500. A gate structure 520 is formed on the P substrate 500 and includes a gate oxide 521 on the P substrate 500, a conducting layer (poly-silicon) 522 on the gate oxide 521 and spacers 523 on two sides of the gate oxide 521 and conducting layer 522. A first and second P+ doped region 531 and 532 are respectively formed in the N well 511 and P well 512, and both sides of the gate structure 520. A P lightly doped region 533 is formed adjacent to the first P+ doped region 531 and beneath one of the spacers 523. An N doped region 540 is formed in the N well 511 and adjacent to the first P+ doped region 531. Field oxides 550 isolate the HVPMOS transistor from other devices on the P substrate 500. The doped regions 540 and 531 form the source of the HVPMOS transistor while the doped region 532 forms the drain of the HVPMOS transistor. The spacing of the second P+ doped region 532 to the edge of the gate structure 520 should be an appropriate value so that the drain side of the HVPMOS sustains a high breakdown voltage. The overlay of the gate structure 520 and the P well 512 is defined as zero. It should be noted that an N+ buried layer 560 is formed beneath the N well 511 and P well 512 for isolation of the P well 512 from the P substrate 500. Further, due to the formation of the N+ buried layer, a P epitaxial layer 570 is formed in the substrate 500. Typically, the HVNMOS and HVPMOS are formed on the same wafer with the same processing steps. The P epitaxial later 570 is also formed in the HVNMOS side of the substrate 400, as shown in FIG. 4.

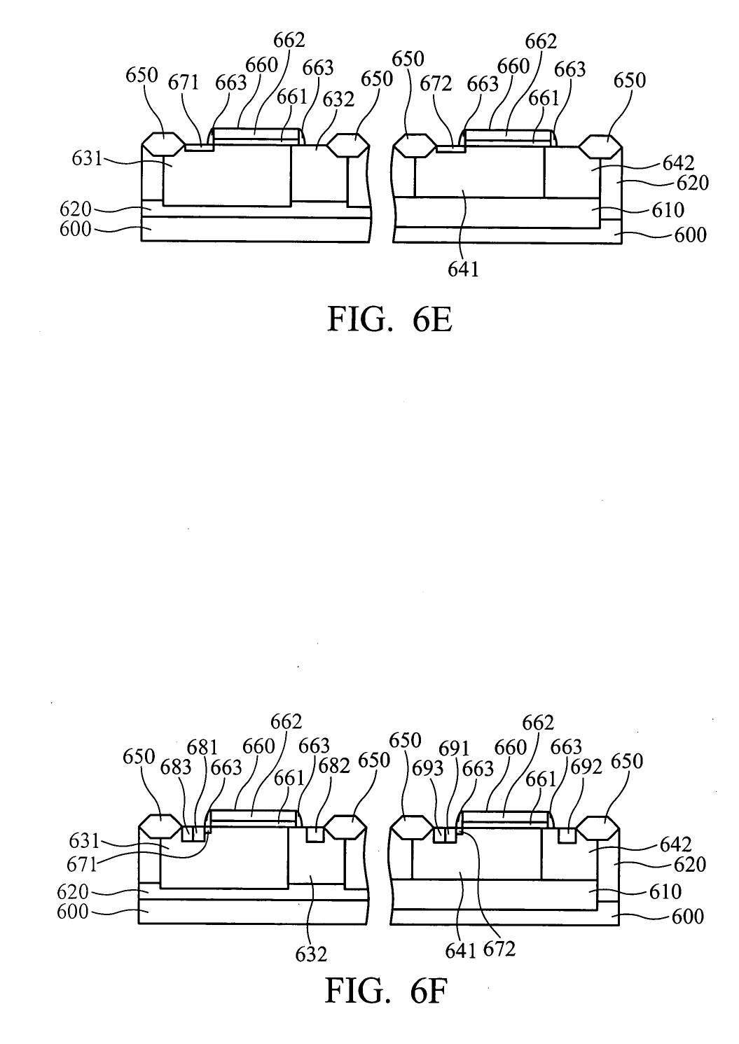

FIG. 6A˜6F are schematic diagrams of manufacturing the high voltage device according to one embodiment of the invention.

As shown in FIG. 6A, the high voltage device is formed on a P substrate 600 and includes a HVNMOS and HVPMOS transistor on different regions of the P substrate 600. The HVNMOS transistor will be formed on the left and HVPMOS on the right. An N+ buried layer 610 is formed in the P substrate 600 on the HVPMOS region. The N+ buried layer 610 is essential to the HVPMOS transistor for isolating the P well 642 from the P substrate 600. Those skilled in the art will appreciate that formation of the N+ buried layer 610 inherently results in formation of a P epitaxial layer 620 in the P substrate 600. Since the P epitaxial layer 620 is formed globally in the substrate 600, it also appears in the HVNMOS region although it is not essential for the HVNMOS transistor.

As shown in FIG. 6B, a P well 631 and N well 632 are formed in the P substrate 600 on the HVNMOS side while an N well 641 and P well 642 are formed in the P substrate 600 on the HVPMOS side. These well regions appear similar to those of the HVMOS transistor with a lateral diffuse drain structure, and functions similarly to the NDD and PDD regions of the HVMOS transistor with a double diffuse drain structure.

As shown in FIG. 6C, a local oxidation process is performed to form field oxide regions 650. The field oxide regions 650 define active regions for the HVNMOS and HVPMOS transistor, which isolate the HVNMOS and HVPMOS transistor from other devices on the P substrate 600.

As shown in FIG. 6D, after performing a series of cleaning and drying processes to the substrate 600, a gate oxide layer with a thickness of 100 to 250 Å is formed on the surface of both the substrate 600 and the field oxides 650 using thermal oxidation. The gate oxide layer is used as the sacrificial oxide layer in the following ion implantation process to protect the silicon structure on the surface of the substrate from the following high energy implantation process. Thereafter, a poly-silicon layer is formed on the gate oxide layer 661, and covers the field oxide layers 650. Then, a photolithographic process is performed using a photoresist layer to define the gate pattern. Thereafter, an etching process is used to remove the polysilicon layer not covered by the photoresist layer in order to form the gate 662. It should be noted that the overlay of the gate 662 to the N well 632 on the HVNMOS side and the gate 662 to the P well 642 on the HVPMOS side must be defined as substantial zero. Next, two ion implantation steps are performed to form lightly doped regions 671 and 672. For the HVNMOS transistor, the first ion implantation step uses phosphorous ions as a dopant, with a dosage of approximately 10¹³/cm². to form the N lightly doped region 671. For the HVPMOS transistor, the second ion implantation step uses boron ions as a dopant to form the P lightly doped region 672.

As shown in FIG. 6E, spacers 663 are formed on two sides of the gate oxides 661 and poly-gate 662. The spacers 663 are formed by a SiO₂ layer deposited by a CVD step and processed by an anisotropic etching step.

As shown in FIG. 6F, N+ doped regions 681, 682 and 693, and P+ doped regions 683, 691 and 692 are formed in the P substrate 600 by two ion implantation steps. For the N+ doped regions 681, 682 and 693, the first ion implantation step uses phosphorous ion as a dopant while the second ion implantation step uses boron ion as a dopant to form the P+ doped regions 683, 691 and 692. It should be noted that the spacing of the N+ doped region 682 to the edge of the gate structure 660, and the P+ doped region 692 to the edge of the gate structure 660 must be properly defined. If the N+ doped region 682 and the P+ doped region 692 are too close to the edge of the gate structure 660, the drain sides of the HVNMOS and HVPMOS transistor will suffer a low breakdown voltage.

Accordingly, compared with the conventional HVMOS transistor with double diffuse drain structure, the HVNMOS or HVPMOS transistor of the present invention has a higher breakdown voltage (more than 30V) and its manufacturing process is simpler as neither an NDD nor a PDD region is necessary. Further, compared with the conventional HVMOS transistor with lateral diffuse drain structure, the HVNMOS or HVPMOS transistor of the present invention has a smaller device size (circuit area) and lower on-state resistance.

In conclusion, the present invention provides a high voltage device combining the advantages of double and lateral diffuse drain structures. The field oxide for releasing electrical field in a lateral diffuse drain structure is eliminated and the NDD or PDD regions used in a double diffuse drain structure are substituted with wells. This results in an HVMOS transistor capable of sustaining a high operating voltage between 20V and 40V without occupying a large circuit area.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

1. A high voltage device comprising:
a substrate of a first type;
a first and second well respectively of the first and a second type in the substrate;
a gate formed on the substrate;
a first and second doped region both of the second type, respectively formed in the first and second well and both sides of the gate; and
a third doped region of the first type in the first well and adjacent to the first doped region.

2. The high voltage device as claimed in claim 1 further comprising field oxides isolating the high voltage device from other devices on the substrate.

3. The high voltage device as claimed in claim 1, wherein the gate comprises a gate oxide on the substrate, a conducting layer on the gate oxide and spacers on two sides of the gate oxide and conducting layer.

4. The high voltage device as claimed in claim 3 further comprising a fourth lightly doped region of the second type adjacent to the first doped region and beneath one of the spacers.

5. The high voltage device as claimed in claim 1, wherein there is a spacing of the second doped region to the gate.

6. The high voltage device as claimed in claim 1, wherein the overlay of the gate and the second well is defined as zero.

7. The high voltage device as claimed in claim 1, wherein the first and second types are respectively P and N type.

8. The high voltage device as claimed in claim 1, wherein the first and second type are respectively N and P type and the high voltage device further comprises a N+ buried layer in the substrate and beneath the first and second well.

9. A high voltage device formed on a P substrate comprising:
an HVNMOS comprising:
a first P and N well in the P substrate;
a first gate formed on the P substrate;
two first N+ doped regions respectively formed in the first P and N well, and both sides of the first gate; and
a first P+ doped region in the first P well and adjacent to the first N+ doped region in the first P well; and
a HVPMOS comprising:
an N+ buried layer in the P substrate;
a second N and P well in the P substrate and above the N+ buried layer;
a second gate formed on the P substrate;
two second P+ doped regions respectively formed in the second N and P well, and both sides of the second gate; and
a second N+ doped region in the second N well and adjacent to the second P+ doped region in the second N well.

10. The high voltage device as claimed in claim 9 further comprising field oxides isolating the HVPMOS and HVNMOS from other devices on the P substrate.

11. The high voltage device as claimed in claim 9, wherein each of the first and second gates comprise a gate oxide on the P substrate, a conducting layer on the gate oxide and spacers on both sides of the gate oxide and conducting layer.

12. The high voltage device as claimed in claim 11, wherein the HVNMOS further comprises an N lightly doped region adjacent to the first N doped region in the first P well and beneath one of the spacers of the first gate, and the HVPMOS further comprises a P lightly doped region adjacent to the second P doped region in the second N well and beneath one of the spacers of the second gate.

13. The high voltage device as claimed in claim 9, wherein there is spacing of the first N+ doped region in the first N well to the first gate and the second P+ doped region in the second P well to the second gate.

14. The high voltage device as claimed in claim 9, wherein the overlay of the first gate and the first P well, and the second gate and the second N well are defined as zero.

15. A method for manufacturing a high voltage device, comprising the steps of:
providing a substrate of a first type;
forming a first and second well respectively of the first and a second type in the substrate;
forming a gate on the substrate;
forming a first and second doped region both of the second type, respectively in the first and second well and both sides of the gate; and
forming a third doped region of the first type in the first well and adjacent to the first doped region.

16. The method as claimed in claim 15 further comprising the step of:
forming field oxides isolating the high voltage device from other devices on the substrate.

17. The method as claimed in claim 15, wherein the gate comprises a gate oxide on the substrate, a conducting layer on the gate oxide and spacers on two sides of the gate oxide and conducting layer.

18. The method as claimed in claim 17 further comprising the step of:
forming a fourth lightly doped region of the second type adjacent to the first doped region and beneath one of the spacers.

19. The method as claimed in claim 15, wherein there is a spacing of the second doped region to the gate.

20. The method as claimed in claim 15, wherein the overlay of the gate and the second well is defined as zero.

21. The method as claimed in claim 15, wherein the first and second type are respectively P and N type.

22. The method as claimed in claim 1, wherein the first and second type are respectively N and P type and the method further comprises the step of:
forming an N+ buried layer in the substrate and beneath the first and second well.

23. A method for manufacturing a high voltage device comprising the steps of:
providing a P substrate;
forming a HVNMOS on the P substrate by:
forming a first P and N well in the P substrate;
forming a first gate on the P substrate;
forming two first N+ doped regions respectively in the first P and N well, and both sides of the first gate; and
forming a first P+ doped region in the first P well and adjacent to the first N+ doped region in the first P well; and
forming a HVPMOS on the P substrate by:
forming an N+ buried layer in the P substrate;
forming a second N and P well in the P substrate and above the N+ buried layer;
forming a second gate on the P substrate;
forming two second P+ doped regions respectively in the second N and P well, and both sides of the second gate; and
forming a second N+ doped region in the second N well and adjacent to the second P+ doped region in the second N well.

24. The method as claimed in claim 23 further comprising the step of:
forming field oxides isolating the HVPMOS and HVNMOS from other devices on the P substrate.

25. The method as claimed in claim 23, wherein each of the first and second gate comprises a gate oxide on the P substrate, a conducting layer on the gate oxide and spacers on both sides of the gate oxide and conducting layer.

26. The method as claimed in claim 25 further comprising the steps of:
forming a N lightly doped region adjacent to the first N doped region in the first P well and beneath one of the spacers of the first gate; and
forming a P lightly doped region adjacent to the second P doped region in the second N well and beneath one of the spacers of the second gate.

27. The method as claimed in claim 23, wherein there is spacing of the first N+ doped region in the first N well to the first gate and the second P+ doped region in the second P well to the second gate.

28. The method as claimed in claim 23, wherein the overlay of the first gate and the first P well, and the second gate and the second N well are defined as zero.
